(19) United States
(12) Patent Application Publication
(10) Pub. No.: US 2024/0413105 A1
(43) Pub. Date: Dec. 12, 2024

(54) CONDUCTIVE LINES FOR INTERCONNECTION IN STACKED DEVICE STRUCTURES

(71) Applicant: BAE SYSTEMS Information and Electronic Systems Integration Inc., Nashua, NH (US)

(72) Inventors: Nathaniel P. Wyckoff, Marion, IA (US); Benjamin Terry, Cedar Rapids, IA (US); Alexander S. Warren, North Liberty, IA (US); Joseph Waggoner, Coralville, IA (US)

(73) Assignee: BAE SYSTEMS Information and Electronic Systems Integration Inc., Nashua, NH (US)

(21) Appl. No.: 18/206,730

(22) Filed: Jun. 7, 2023

(51) Int. Cl. H01L 23/00

(52) U.S. Cl. CPC H01L 24/05; H01L 24/03; H01L 24/16; H01L 24/17; H01L 24/81; H01L 2224/02311; H01L 2224/02313; H01L 2224/02371; H01L 2224/0401; H01L 2224/16145; H01L 2224/17181; H01L 2224/81801

(57) ABSTRACT

A microelectronics device structure includes a device having (i) a lower surface, (ii) an upper surface opposite the lower surface, and (iii) a side surface extending between the lower surface and the upper surface. The integrated circuit structure further includes a conductive line having (i) a first section on the upper surface, (ii) a second section on the side surface, and (iii) a third section on the lower surface. In an example, the first section and the second section of the conductive line is a monolithic conductive structure, with no seam or interface between the first section and the second section. Additionally or alternatively, in an example, the second section and the third section of the conductive line is a monolithic conductive structure, with no seam or interface between the second section and the third section.

### TECHNICAL FIELD

The present disclosure relates generally to integrated circuits, and more specifically to interconnections between stacked integrated circuit devices.

### BACKGROUND

In a vertically stacked integrated circuit device configuration, an upper device is stacked above a lower device, and there may be one or more additional devices above and/or below the combination of the upper and lower devices. The devices may be integrated circuit dies and/or integrated circuit packages. The lowermost device of the stack may be coupled to a circuit board, such as a printed circuit board (PCB). To facilitate communication between an upper device and a PCB, wire bonding techniques may be employed, where the upper device is coupled to the PCB through a plurality of wire bonds. In another example, through silicon vias (TSVs) may be formed within the lower device, where the TSVs extend from an upper surface of the lower device to a lower surface of the lower device, and the upper device is coupled to the underlying PCB through the TSVs, solder balls, solder bumps, and/or other integrated components.

### BRIEF DESCRIPTION OF THE DRAWINGS

FIG. 1 illustrates a cross-sectional view of an integrated circuit structure comprising (i) a first device, (ii) a second device above the first device, (iii) a third device below the first device, (iv) a conductive line extending on an upper surface, a lower surface, and a side surface of the first device, (v) a first interconnect component coupled between the second device and a section of the conductive line that is on the upper surface of the first device, and (vi) a second interconnect component coupled between the third device and another section of the conductive line that is on the lower surface of the first device, in accordance with an embodiment of the present disclosure.

FIG. 2 illustrates the conductive line and the first device of FIG. 1 in further detail, in accordance with an embodiment of the present disclosure.

FIG. 3 illustrates a plan or top view of the first device of FIGS. 1 and 2, with corresponding sections of multiple conductive lines on the upper surface of the first device, in accordance with an embodiment of the present disclosure.

FIG. 4 illustrates a perspective view of the first device of FIGS. 1-3, with a plurality of conductive lines on one or more surfaces of the first device, in accordance with an embodiment of the present disclosure.

FIG. 5 illustrates another perspective view of the first device of FIGS. 1-4, with a plurality of conductive lines on one or more surfaces of the first device, in accordance with an embodiment of the present disclosure.

FIG. 6A illustrates magnified views of a portion of a first conductive line described with respect to FIGS. 1-5, FIG. 6B illustrates magnified views of a portion of a second conductive line that may be formed using an additive process, and FIG. 6C illustrates magnified views of a portion of a third conductive line that may be formed using a lithography process, in accordance with an embodiment of the present disclosure.

FIG. 7 illustrate a flowchart depicting a method 700 for forming a conductive line of the integrated circuit structure of FIGS. 1-5, in accordance with an embodiment of the present disclosure.

FIGS. 8A1, 8A2, 8B1, 8B2, 8C1, 8C2, 8D1, 8D2, and 8E collectively illustrate an example integrated circuit structure in various stages of processing in accordance with the methodology of FIG. 7, in accordance with an embodiment of the present disclosure.

The figures depict various embodiments of the present disclosure for purposes of illustration only and are not necessarily drawn to scale. Numerous variations, configurations, and other embodiments will be apparent from the following detailed discussion.

### DETAILED DESCRIPTION

Disclosed herein are integrated circuit structures that include one or more conductive lines extending on multiple surfaces of a first device, wherein the one or more conductive lines facilitate interconnection between (i) a second device that is above the first device and (ii) a third device that is below the first device. In an example, each of the first, second, third devices may be, for instance, an integrated circuit die, an integrated circuit package, or a circuit board (e.g., a PCB). In one such example, the first device is a first integrated circuit die, the second device is a second integrated circuit die, and the third device is an integrated circuit package, although other combinations can be used.

For example, the first device has (i) a lower surface, (ii) an upper surface opposite the lower surface, and (iii) a side surface extending between the lower surface and the upper surface. In some such examples, a conductive line extends on the lower, side, and upper surfaces of the first device, such that the conductive line has multiple sections, each being on a corresponding surface of the first device. For example, the conductive line has (i) a first section on the upper surface, (ii) a second section on the side surface, and (iii) a third section on the lower surface of the first device. In one such example, at least two adjacent sections of the conductive line form a conductive monolithic structure, e.g., there is no seam or interface between the at least two adjacent sections. Thus, at least one of (i) the first section and the second section of the conductive line is a monolithic conductive structure, such that there is no seam or interface between the first section and the second section, and (ii) the second section and the third section of the conductive line is a monolithic conductive structure, such that there is no seam or interface between the second section and the third section.

In some examples, the second device above the first device is coupled to the first section of the conductive line (e.g., which is on the upper surface of the first device) through a first interconnect component. Also, the third device below the first device is coupled to the third section of the conductive line (e.g., which is on the lower surface of the first device) through a second interconnect component. In one such example, each of the first interconnect component and the second interconnect component is a solder ball or a solder bump (or may be a gold stud bump, thermosonic bond, anisotropic conductive paste, or another appropriate interconnect component, for example). Thus, the conductive line on multiple surfaces of the first device couples (i) the second device that is stacked above the first device and (ii) the third device that is below the first device.

In one embodiment, the conductive line is formed using a subtractive process. For example, first conductive material may be deposited on a first surface of the first device, and the first conductive material on the first surface may be patterned (e.g., using a laser beam), to form a first section of the conductive line. Also, second conductive material may be deposited on a second surface and a third surface of the first device, and the second conductive material on the second and third surfaces may be patterned (e.g., using a laser beam), to form a second section and a third section of the conductive line on the second surface and the third surface, respectively, of the first device. In an example, the conductive line is a continuous structure that extends on the first surface, the second surface, and the third surface of the integrated circuit device. Numerous variations and embodiments will be apparent in light of the present disclosure.

### General Overview

As described above, in a stacked device configuration, TSVs may be formed within an intermediate device, to interconnect an upper device (e.g., which is above the intermediate device) to a lower device (e.g., which is below the intermediate device) through the TSVs of the intermediate device. However, it may be costly and time consuming to design and form TSVs through integrated circuit devices. Also, if such devices are configured with a flip-chip mounting configuration, wire bonding may not be usable for interconnecting such stacked devices.

Accordingly, techniques are described herein to form one or more conductive lines extending on multiple surfaces of a first device, wherein the one or more conductive lines facilitate interconnection between (i) a second device that is above the first device and (ii) a third device that is below the first device. In an example, each of the first, second, third devices may be any one of an integrated circuit die, an integrated circuit package, or a circuit board (e.g., a PCB).

For example, the first device has (i) a lower surface, (ii) an upper surface opposite the lower surface, and (iii) a plurality of side surfaces extending between the lower surface and the upper surface. In one such example, each such one or more conductive lines is a continuous conductive structure extending on the upper surface of the first device, a corresponding side surface of the first device, and the lower surface of the first device. In an example where there are four side surfaces of the first device, the conductive lines may be on one, two, three, or all four side surfaces of the first device.

The following description is associated with one conductive line on multiple surfaces of the first device, and such description also applies to multiple other such conductive lines on the surfaces of the first device. In some examples, the second device (e.g., which is above the first device) is coupled to a section of the conductive line that is on the upper surface of the first device, though an interconnect component (such as a solder bump or solder ball, gold stud bump, thermosonic bond, anisotropic conductive paste, or other appropriate interconnect component). In some such examples, the third device (e.g., which is below the first device) is coupled to a section of the conductive line that is on the lower surface of the first device, though another interconnect component (such as a solder bump or solder ball, gold stud bump, thermosonic bond, anisotropic conductive paste, or other appropriate interconnect component). Thus, the second device is coupled to the third device through the conductive line that is on each of the upper surface, side surface, and lower surface of the first device. In an example, as the conductive line provides such interconnection between the second and third devices, no TSVs through the first device are needed.

In one embodiment, the conductive line is formed using a subtractive process. In one example, first conductive material may be deposited on a first surface of the first device, and the first conductive material on the first surface may be patterned (e.g., using a laser beam or other subtractive forming process), to form a first section of the conductive line. Also, second conductive material may be deposited on a second surface and a third surface of the first device, and the second conductive material on the second and third surfaces may be patterned (e.g., using a laser beam or other subtractive forming process), to form a second section and a third section of the conductive line on the second surface and the third surface, respectively, of the first device. In another example, the conductive material is deposited on the first, second, and third surfaces using a same deposition process, and then patterned using a same patterning process.

In an example, the conductive line is a continuous structure that extends on the first surface, the second surface, and the third surface of the integrated circuit device. The conductive line has multiple sections, each being on a corresponding surface of the first device. For example, the conductive line has (i) a first section on the upper surface, (ii) a second section on the side surface, and (iii) a third section on the lower surface of the first device.

Because, in some examples, the conductive line is formed using a subtractive process, two or more adjacent sections of the conductive line may be monolithic, e.g., there is no seam or interface between the two or more adjacent sections of the conductive line. For example, as the conductive material is deposited in a same deposition process on two or more surfaces of the first device, the corresponding two or more sections of the conductive line may not have any seam or interface therebetween. Thus, (i) the first section and the second section of the conductive line is a monolithic conductive structure, with no seam or interface between the first section and the second section, and/or (ii) the second section and the third section of the conductive line is a monolithic conductive structure, with no seam or interface between the second section and the third section.

In one embodiment, within a section of the conductive line, there may be various segments extending in corresponding various directions. For example, for a given section of the conductive line, a first segment is at an angle different from 180 degrees relative to an adjacent segment (e.g., two adjacent segments do not form a straight line, and extend in different directions). Thus, a segment of a conductive line is a straight portion of the conductive line, without any bend or curve or other direction-changing feature therewithin.

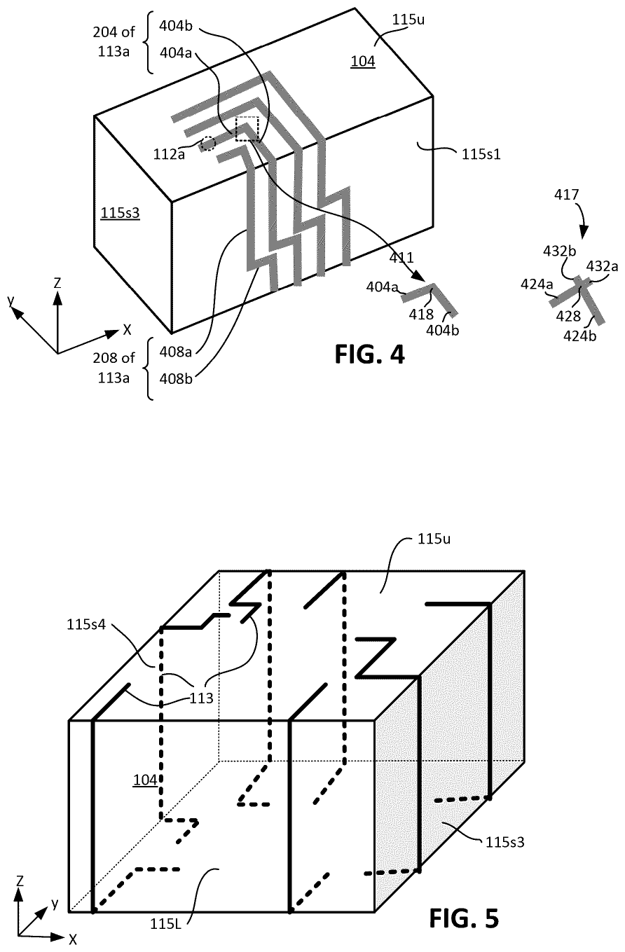

In one embodiment, as described below in further detail, as the conductive line is formed using a subtractive process, an intersection point between two adjacent segments is sharp, with no overhangs of the segments beyond the intersection point (e.g., see FIG. 4). In some such examples, such precise intersection is possible because of use of a laser beam in patterning the conductive line from blanket deposited conductive material. In contrast, conductive lines formed using an additive process (described below) may have imperfectly aligned segments and overhangs of the segments at intersection points.

Additionally, for the conductive line described herein that is formed using the subtractive process, there is no seam or interface between the adjacent segments of a section of the conductive line. In contrast, conductive lines formed using an additive process may have seam or interface between the adjacent segments of a section of the conductive line.

Moreover, for an additively formed conductive line, conductive material on an intersection point of two segments are deposited twice (e.g., deposited as a part of formation of a first segment, and also deposited as a part of formation of a second segment). This results in an increase in thickness of the conductive material at the intersection point for an additively formed conductive line. In contrast, a thickness of the conductive line formed using the subtractive process described herein is substantially uniform (e.g., as conductive material for the entire section, including adjacent segments, is blanket deposited using a same deposition process, and then patterned).

In accordance with some embodiments of the present disclosure, these various approaches can be used individually or together to form conductive lines using a subtractive process, where the conductive lines facilitate in interconnections between stacked devices. Numerous variations and embodiments will be apparent in light of the present disclosure.

As used in the discussion and claims herein, the term “about” indicates that the value listed may be somewhat altered, as long as the alteration does not result in nonconformance of the process or device. For example, for some elements the term “about” can refer to a variation of +0.1%, for other elements, the term “about” can refer to a variation of +1% or +10%, or any point therein. As also used herein, terms defined in the singular are intended to include those terms defined in the plural and vice versa.

Reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc.

As used herein, the term “substantially”, or “substantial”, is equally applicable when used in a negative connotation to refer to the complete or near complete lack of an action, characteristic, property, state, structure, item, or result. For example, a surface that is “substantially” flat would either completely flat, or so nearly flat that the effect would be the same as if it were completely flat.

### Architecture

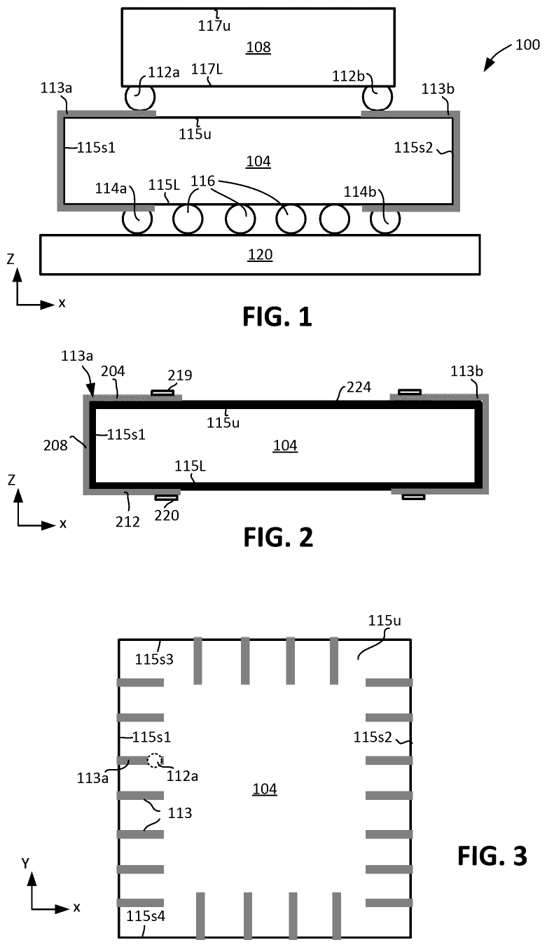

FIG. 1 illustrates a cross-sectional view of an integrated circuit structure 100 comprising (i) a first device 104, (ii) a second device 108 above the first device 104, (iii) a third device 120 below the first device 104, (iv) a conductive line 113a extending on an upper surface 115u, a lower surface 115L, and a side surface 115s1 of the first device 104, (v) a first interconnect component 112a coupled between the second device 108 and a section of the conductive line 113a that is on the upper surface 115u of the first device 104, and (vi) a second interconnect component 114a coupled between the third device 120 and another section of the conductive line 113a that is on the lower surface 115L of the first device 104, in accordance with an embodiment of the present disclosure.

In an example, the structure 100 includes three stacked devices 104, 108, 120, although the structure 100 may include more than three stacked devices, such as four or five stacked devices. In one embodiment, each of the devices 104, 108, 120 may be any appropriate integrated circuit device, such as a processor or logic die, a memory die, an integrated circuit package, a circuit board (e.g., a printed circuit board (PCB)), for example. For example, one or more of the devices 104, 108, 120 include active devices such as a plurality of transistors, memory cells, logic cells, passive devices such as resistors, inductors, and capacitors, and/or one or more other components of microelectronic dies and packages. For example, the device 108 is an integrated circuit die or an integrated circuit package, the device 104 is an integrated circuit die or an integrated circuit package, and the device 120 is an integrated circuit die, an integrated circuit package, or a circuit board (e.g., a PCB).

In an example, where the devices 104 and 108 are integrated circuit dies and the device 120 is a package carrier substrate, the device 104 is coupled to the package carrier substrate 120 in a flip-chip configuration, e.g., such that the active lower surface 115L of the device 104, having interconnect components 116, is facing the device 120. The devices 104 and 108 form a vertical stack of dies.

The device 104 comprises six surfaces, such as the upper surface 115u, the lower surface 115L, and four side surfaces 115s1, 115s2, 115s3, and 115s4, although only two side surfaces 115s1, 115s2 are visible in the cross-sectional view of FIG. 1. The upper surface 115u of the device 104 faces the device 108, the lower surface 115L of the device 104 is opposite the upper surface 115u and faces the device 120, and each of the side surfaces 115s1, 115s2, 115s3, and 115s4 extends between the upper surface 115u and the lower surface 115L. Note that in an example, the corners of the device 104 and/or the section of the device 104 between two surfaces may be chamfered. For example, chamfering the corners may improve reliability in formation of the conductive lines described herein.

Similarly, the device 108 comprises six surfaces, such as an upper surface 117u, a lower surface 117L, and four side surfaces that are not specifically labelled, although only two side surfaces are visible in the cross-sectional view of FIG. 1. The lower surface 117L of the device 108 faces the device 104, the upper surface 117u of the device 108 is opposite the lower surface 117L, and each of the side surfaces extends between the upper surface 117u and the lower surface 117L, as illustrated.

In one embodiment, the lower surface 115L of the device 104 is an active surface of the device 104, e.g., a surface through which the components of the device 104 is coupled to outside circuits. For example, a plurality of interconnect components 116 couples the device 104 (such as the lower surface 115L of the device 104) to the device 120. In an example, the interconnect components 116 are conductive balls or bumps, such as solder balls or solder bumps (or may comprise gold stud bump, thermosonic bond, anisotropic conductive paste, or other appropriate interconnect component, for example). For example, the device 104 is an integrated circuit package or an integrated circuit die, and the interconnect components 116 couple the device 104 to a PCB 120 in a ball grid array (BGA) configuration or another appropriate configuration. In an example, each interconnect component 116 is coupled to the lower surface 115L of the device 104 through a corresponding contact pad that is on the lower surface 115L of the device 104. Note that interconnect components 114a and 114b are also illustrated to be coupled to the lower surface 115L of the device 104, and these interconnect components 114a and 114b will be described below.

In one embodiment, the structure 100 further comprises a conductive line 113a and a conductive line 113b (illustrated using thick gray lines in FIG. 1), where each of the conductive lines 113a, 113b extends on the upper surface 115u, the lower surface 115L, and a side surface 115s1 or 115s2 of the device 104, as illustrated in FIG. 1. Although the device 104 is likely to have more than two such conductive lines 113a, 113b on its surface, only two such conductive lines 113a, 113b are visible in the cross-sectional view of FIG. 1. The conductive lines 113a, 113b may have a width in the range of 1-100 microns, or in the subrange of 1-80 microns, or 1-50 microns, or 1-25 microns, or 1-10 microns, or 10-100 microns, or 25-100 microns, for example.

As illustrated, an interconnect component 112a is between, and electrically couples, the lower surface 117L of the device 108 and a section of the line 113a that is on the upper surface 115u of the device 104. For example, the interconnect component 112a is coupled to the lower surface 117L of the device 108 through a corresponding conductive contact pad, and is coupled to the upper surface 115u of the device 104 through another corresponding conductive contact pad (e.g., contact pad 219, see FIG. 2).

Similarly, another interconnect component 112b is between, and electrically couples, the lower surface 117L of the device 108 and a section of the line 113b that is on the upper surface 115u of the device 104. For example, the interconnect component 112b is coupled to the lower surface 117L of the device 108 through another corresponding conductive contact pad, and is coupled to the upper surface 115u of the device 104 through another corresponding conductive contact pad. In an example, the interconnect components 112a, 112b are conductive balls or bumps, such as solder balls or solder bumps (or may comprise gold stud bump, thermosonic bond, anisotropic conductive paste, or another appropriate interconnect component, for example).

As illustrated, an interconnect component 114a is between, and electrically couples, (i) a section of the line 113a that is on the lower surface 115L of the device 104 and (ii) the device 120. For example, the interconnect component 114a is coupled to the lower surface 115L of the device 104 through a corresponding conductive contact pad (e.g., contact pad 220, see FIG. 2), and is coupled to an upper surface of the device 120 through a corresponding conductive contact pad.

Similarly, another interconnect component 114b is between, and electrically couples, (i) a section of the line 113b that is on the lower surface 115L of the device 104 and (ii) the device 120. For example, the interconnect component 114b is coupled to the lower surface 115L of the device 104 through a corresponding conductive contact pad, and is coupled to the upper surface of the device 120 through another corresponding conductive contact pad. In an example, the interconnect components 114a, 114b are conductive balls or bumps, such as solder balls or solder bumps (or may comprise gold stud bump, thermosonic bond, anisotropic conductive paste, or another appropriate interconnect component, for example).

Thus, in FIG. 1, the device 108 is electrically coupled to the device 120 through the interconnect component 112a, the conductive line 113a, and the interconnect component 114a. Thus, the conductive line 113a facilitates in electrically coupling the device 108 to the device 120. Similarly, the conductive line 113b also facilitates in electrically coupling the device 108 to the device 120. Because the conductive lines 113a, 113b electrically couples the device 108 to the device 120, through silicon vias (TSVs) through the device 104 to couple the devices 108 and 120 may not be needed, thereby avoiding cost and complexity associated with forming such TSVs through the device 104.

FIG. 2 illustrates a conductive line 113a of FIG. 1 and the first device 104 in further detail, in accordance with an embodiment of the present disclosure. For example, the conductive line 113a has a first section 204 on the upper surface 115u of the device 104, a second section 208 on the side surface 115s1 of the device 104, and a third section 212 on the lower surface 115L of the device 104. In an example and as will be described below, the conductive line 113a is formed using a subtractive process. For example, to form a section of the conductive line 113a on a surface of the device 104, conductive material is blanket deposited on at least a portion of the surface of the device 104. Subsequently, the blanket deposited conductive material is patterned (e.g., using laser beams), to form the section of the conductive line 113a on the surface of the device 104. In one embodiment, the conductive material may be deposited simultaneously on one or more surfaces of the device 104, and subsequently patterned.

For example, the conductive material may be deposited (e.g., deposited conformally) on the upper surface 115u and the side surface 115s1 of the device 104 using a same deposition process. Accordingly, a monolithic and continuous layer of conductive material will be on the upper surface 115u and the side surface 115s1 of the device 104, without any seam or interface between a portion of the conductive material that is on the upper surface 115u and another portion of the conductive material that is on the side surface 115s1. Thus, after patterning, the sections 204 and 208 of the conductive line 113a would not have any seam or interface therebetween, e.g., the sections 204 and 208 will form a monolithic conductive structure.

In another example, the conductive material may be deposited on the upper surface 115u, the side surface 115s1, and the lower surface 115L of the device 104 using a same deposition process. Accordingly, for reasons described above, the conductive line 113a would not have any seam or interface between sections 204 and 208, and also would not have any seam or interface between sections 208 and 212. Thus, the entire conductive line 113a would be a monolithic conductive structure.

In yet another example, the conductive material may be deposited on the side surface 115s1 and the lower surface 115L of the device 104 using a same deposition process. Accordingly, for reasons described above, the conductive line 113a would not have any seam or interface between sections 208 and 212, e.g., the sections 208 and 212 will form a monolithic conductive structure.

Note that as described herein, the conductive line 113a is formed using a subtractive process, which results in no seam or interface between sections 204 and 208 of the conductive line 113a, and/or between sections 208 and 212 of the conductive line 113a, as described above. In contrast, as described below with respect to FIG. 4, for an additively formed conductive line (where the additive process is also discussed with respect to FIG. 4), because two adjacent sections of the additively formed conductive line (e.g., which are on two adjacent surfaces of the corresponding device) are deposited using two different deposition processes, there would be a seam or an interface between any two adjacent sections.

Also illustrated in FIG. 2 are two contact pads 219 and 220 (which are not illustrated in FIG. 1 for purposes of illustrative clarity). The contact pad 219 is on the section 204 of the conductive line 113a, and configured to receive the interconnect component 112a. The contact pad 220 is on the section 212 of the conductive line 113a, and configured to receive the interconnect component 114a.

As illustrated in FIG. 2, in one embodiment, the device 104 comprises a layer 224 of dielectric material (illustrated using a thick black line) on at least some portions of the various surfaces of device 104. The layer 224 of dielectric material illustrated in FIG. 2 is not illustrated in FIG. 1, for purposes of illustrative clarity. In an example, below the layer 224 of dielectric material is a body of the device 104, where the body comprises bulk silicon, or another appropriate material, e.g., depending on a technology used to form the device 104. If the conductive lines 113 are directly on a semiconductor material body (such as bulk silicon, or a body comprising another semiconductor material, for example) of the device 104, this may cause electrical shorting between the conductive lines 113 and the semiconductor material of the body the device 104. However, the layer 224 of dielectric material prevents or at least reduces such chances of electrical shorting. In one example, additionally (or alternatively), the layer 224 of dielectric material may act as a patterning stop layer, such as a laser stop layer, when blanket-deposited conductive material on surfaces of the device 104 is patterned to form the conductive lines 113.

FIG. 3 illustrates a plan or top view of the first device 104 of FIGS. 1 and 2, with corresponding sections of the conductive lines 113 on the upper surface 115u of the first device 104, in accordance with an embodiment of the present disclosure. In the plan view of FIG. 3, outlines of all four side surfaces 115s1, 115s2, 115s3, and 115s4 are visible. In the example of FIG. 3, (i) first one or more of a plurality of conductive lines 113 extend from the upper surface 115u to the side surface 115s1 (such as conductive line 113a of FIG. 1), (ii) second one or more of the plurality of conductive lines 113 extend from the upper surface 115u to the side surface 115s2 (such as conductive line 113b of FIG. 1), (iii) third one or more of the plurality of conductive lines 113 extend from the upper surface 115u to the side surface 115s3, and (iv) fourth one or more of the plurality of conductive lines 113 extend from the upper surface 115u to the side surface 115s4.

Thus, in the example of FIG. 3, conductive lines are formed on all the side surfaces 115s1, . . . , 115s4. However, in another example, there may be conductive lines 113 extending from the upper surface 115u to one or more, but not all, the side surfaces 115s1, . . . , 115s4 of the device 104.

FIG. 3 also illustrates (using dotted line) an outline of the interconnect component 112a on the conductive line 113a. Other conductive lines may also include corresponding interconnect components, e.g., which may be solder balls or solder bumps (or may comprise gold stud bump, thermosonic bond, anisotropic conductive paste, or another appropriate interconnect component), for example.

FIG. 4 illustrates a perspective view of the first device 104 of FIGS. 1-3, with a plurality of conductive lines 113 on one or more surfaces of the first device 104, in accordance with an embodiment of the present disclosure. In the example of FIG. 4, multiple conductive lines 113 are illustrated, including the conductive line 113a described above with respect to FIGS. 1-3.

Two side surfaces 115s1 and 115s3 are illustrated in FIG. 4, along with the upper surface 115u. Conductive lines 113 on the upper surface 115u and the side surface 115s1 are illustrated. There may similarly be conductive lines on the upper surface 115u and the side surface 115s3, although such conductive lines are not illustrated in FIG. 4.

The conductive line 113a labeled in FIG. 4 is described below, and such description may also apply to one or more other conductive lines 113. As seen, the conductive line 113a has various segments 404a, 404b, 408a, 408b, where a segment is at an angle different from 180 degrees relative to an adjacent segment (e.g., two adjacent segments do not form a straight line, and extend in different directions). Thus, a segment of a conductive line is a straight portion of the conductive line, without any bend or curve therewithin.

For example, as described with respect to FIG. 2 and as also illustrated in FIG. 4, the conductive line 113a has a first section 204 on the upper surface 115u of the device 104, a second section 208 on the side surface 115s1 of the device 104, and a third section 212 on the lower surface 115L of the device 104 (where the third section 212 is not visible in the perspective view of FIG. 4). As illustrated in FIG. 4, each such section may have one or more segments that are at an angle relative to an adjacent segment.

For example, section 204 of the conductive line 113a (e.g., which is on the upper surface 115u) has a first segment 404a and a second segment 404b, where the segments 404a and 404b are at an angle different from 180 degrees (e.g., the angle is about 90 degrees in the example of FIG. 4). Similarly, section 208 of the conductive line 113a (e.g., which is on the side surface 115s1) has a first segment 408a and a second segment 408b, where the segments 408a and 408b are at an angle different from 180 degrees (e.g., where the angle is an obtuse angle in the example of FIG. 4).

Note that a number of segments and angles at adjacent segments, as illustrated in FIG. 4, are mere examples, and the conductive line 113a can have more or less segments per section, and adjacent segments can be at different angles.

As described below, the conductive line 113a is formed using a subtractive process. For example, to form a section of the conductive line 113a, conductive material is blanket deposited on a corresponding surface of the die 104, and then the section of the conductive line 113a is patterned using, for example, a laser beam. Because the conductive line 113a is patterned using a laser beam, it is relatively easy to have arbitrary number of segments and/or arbitrary angles between the segments (e.g., which may be achieved by moving the laser beam with a specified pattern on the blanket-deposited conductive material). For example, there can be one, two, three, or higher number of segments within a corresponding section (such as sections 204, 208) of the conductive line 113a.

In contrast, a conductive line may also be formed using an additive process, e.g., where each segment of a section of the conductive line is deposited using a corresponding deposition process and a corresponding mask, and no blanket deposition and patterning of the deposited material is involved. Thus, for an additively formed conductive line, forming two or more segments per section of the conductive line necessitates correspondingly two or more masks, making the formation process challenging. Accordingly, if a conductive line is formed additively, a section of the conductive line may have only one corresponding segment, e.g., due to challenges of forming multiple segments per section of the conductive line.

FIG. 4 also illustrates a magnified view of a portion 411 of the conductive line 113a formed using the subtractive process, where the portion 411 illustrates the segment 404a conjoining the segment 404b. As illustrated, an intersection point 428 between the segments 404a and 404b is sharp, with no overhangs of the segments 404a, 404b. Such precise intersection is possible because of use of the laser beam in patterning the conductive line 113a from blanket deposited conductive material.

FIG. 4 also illustrates a portion 417 of a conductive line that is formed using the above described additive process. For example, as described above, it is challenging to form a multi-segment conductive line using the additive process, as formation of each segment necessitates a corresponding mask and a corresponding deposition process. Additionally, even if the additive process is used to form a two segment section, the segments would not be perfectly aligned, as illustrated, e.g., due to practical difficulty in perfectly aligning masks for forming the segments. For example, the additively formed portion 417 includes segments 424a and 424b, with an intersection point 428 between the segments 424a, 424b. Because two different masks are used to form the two segments 424a and 424b, the two segments 424a and 424b are most likely to be not aligned (e.g., due to practical difficulty in perfectly aligning masks for forming the segments), with overhang 432a of the segment 424a crossing the intersection point 428, and with overhang 432b of the segment 424b crossing the intersection point 428, as illustrated in FIG. 4.

Additionally, for the additively formed conductive line, because the two segments 424a and 424b are deposited using two different deposition processes, there would be a seam or an interface between the segments 424a and 424b. In contrast, for the conductive line 113a formed using the subtractive process, there is no seam or interface between the segments 404a and 404b, as the conductive material deposition process is common for both the segments 404a, 404b.

For similar reasons, because two sections of an additively formed conductive line (e.g., which are on two surfaces of the corresponding device) are deposited using two different deposition processes, there would be a seam or an interface between any two adjacent sections. In contrast, as described above with respect to FIG. 2, there may not be a seam or interface between sections 204 and 208 of the conductive line 113a, and/or between sections 208 and 212 of the conductive line 113a.

Moreover, for the additively formed conductive line, conductive material on the intersection point 428 of the two segments 424a and 424b are deposited twice (e.g., deposited as a part of formation of the segment 424a, and also deposited as a part of formation of the segment 424b). This results in an increase in thickness of the conductive material at the intersection point 428. Thus, for the additively formed conductive line, a thickness of the conductive line at the intersection point of two segments is about twice a thickness of the conductive line at non-intersection portions.

In contrast, a height or thickness of the conductive line 113a formed using the subtractive process is substantially uniform (e.g., as conductive material for the entire section 204 is blanket deposited using a same deposition process, and then patterned). For example, a thickness of a section 204 of the conductive line 113 (e.g., measured in a direction perpendicular to the length and width of the conductive line 113a, such as the vertical of Z-axis direction in FIG. 4) may be T1 at the intersection point 418 of the two segments 404a and 404b, and may be T2 at non-intersecting portions of the two segments. In an example, T1 and T2 are substantially the same. For example, the thickness T1 and T2 differs by at most 20% of any of the thicknesses T1 and T2, by at most 15% of any of the thicknesses T1 and T2, by at most 10% of any of the thicknesses T1 and T2, by at most 5% of any of the thicknesses T1 and T2, by at most 2% of any of the thicknesses T1 and T2, or by at most 1% of any of the thicknesses T1 and T2.

FIG. 5 illustrates another perspective view of the first device 104 of FIGS. 1-4, with a plurality of conductive lines 113 on one or more surfaces of the first device 104, in accordance with an embodiment of the present disclosure. For example, all six surfaces of the device 104 is visible in FIG. 5. A plurality of example conductive lines 113 are illustrated. The device 104 is illustrated to be transparent for purposes of illustrative clarity. Sections of conductive lines, which would otherwise be not visible for being behind a surface of the device 104, are illustrated using dotted lines in FIG. 5. Some of the conductive lines are illustrated having segments within a section of the conductive line. Note that the location, numbers, and/or shape of the conductive lines, as illustrated in FIG. 5, are mere examples. FIG. 5 will be apparent, based on the above description with respect to FIGS. 1-4.

In an example, a first conductive line may have to cross a second conductive line, e.g., to form an interconnect structure comprising a redistribution layer (RLD), e.g., to facilitate better routing of the conductive lines. In such an example, a dielectric material is deposited between the two conductive lines. For example, when forming the conductive lines (described herein later), a first conductive material may be deposited and patterned to form the first conductive line. This may be followed by deposition of second conductive material above the first conductive line and patterning of the second conductive material, to form the second conductive line. Thus, the first and second conductive lines may cross each other, and may be separate by the intervening layer of dielectric material (e.g., to avoid electrical shorting of the two conductive lines).

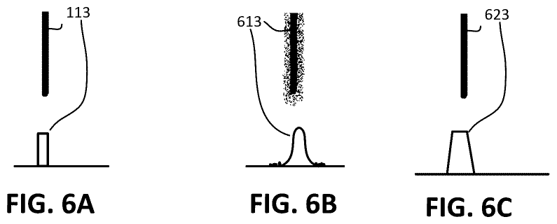

FIG. 6A illustrates magnified views of a portion of a first conductive line 113 described above with respect to FIGS. 1-5, FIG. 6B illustrates magnified views of a portion of a second conductive line 613 that may be formed using an additive process, and FIG. 6C illustrates magnified views of a portion of a third conductive line 623 that may be formed using a lithography process, in accordance with an embodiment of the present disclosure. Each of FIGS. 6A-6C illustrates a plan view of the corresponding line on the top of the figure and a cross-sectional view of the corresponding line on the bottom of the figure. For example, as illustrated in FIG. 6A, the conductive line 113 formed using a subtractive process is patterned using a laser beam, resulting in a sharp or crisp edge, as illustrated in the plan view. Also, as illustrated in the cross-sectional view, the corners are substantially 90 degrees, resulting in a square or a rectangular cross-sectional shape. In contrast, in FIG. 6B, for the additively formed conductive line 613, the conductive material is deposited using one or more masks. This results in a main path of conductive material directly below a mask, and some conductive material on two sides of the main path, as illustrated in FIG. 6B. Thus, the edges of the conductive line 613 is more blur than the edges of the conductive line 113, as illustrated in FIG. 6B. Also, due to the additive nature of the deposition process using masks, the cross-sectional view has a bell-shape in FIG. 6B. The line 623 formed by the lithography process may be sharp (e.g., similar plan views in FIGS. 6A and 6C). However, the cross-sectional view of line 623 may have a trapezoid shape, as illustrated in FIG. 6C.

### Formation Methodology

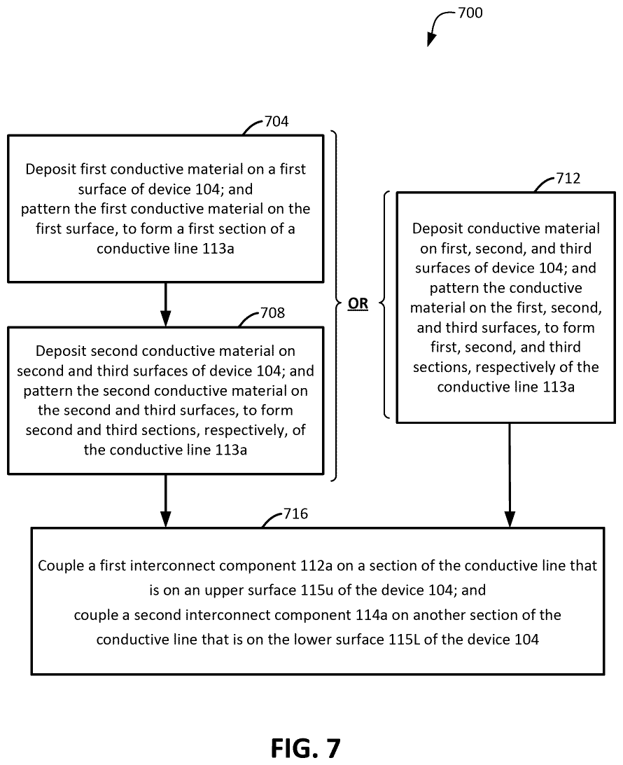

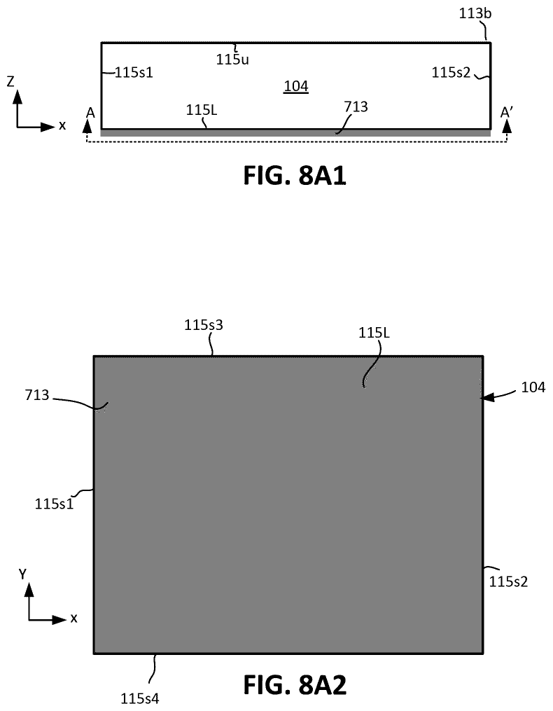

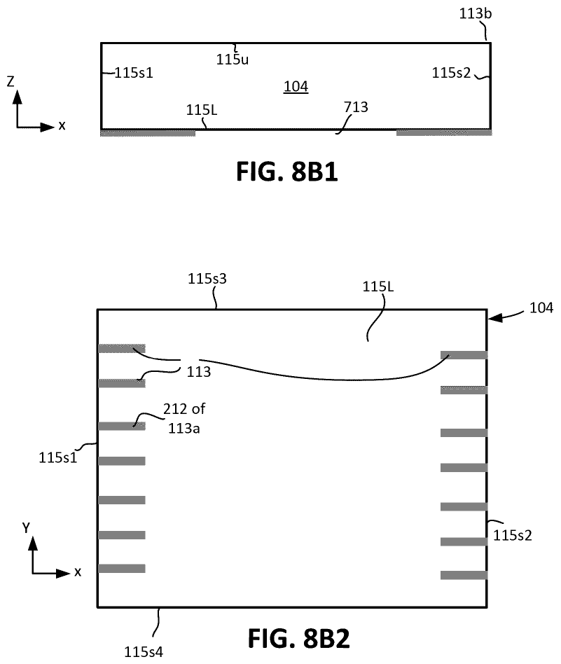

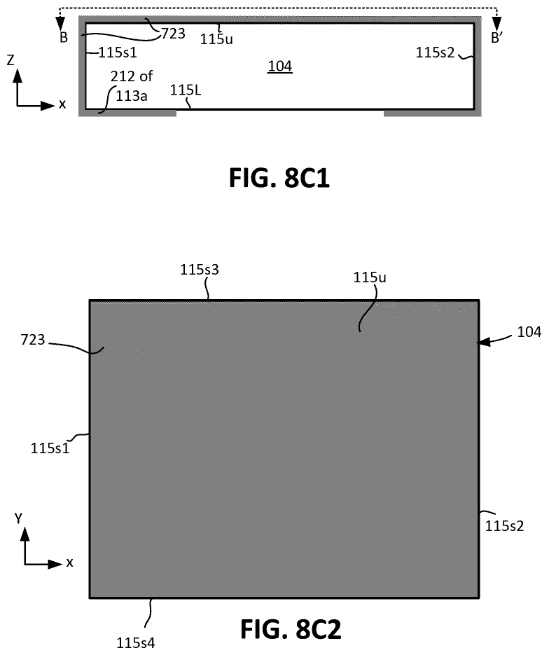

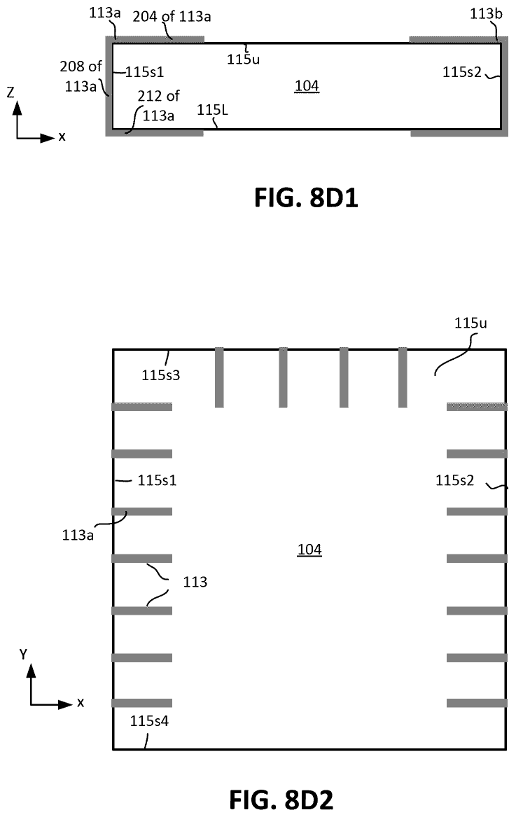

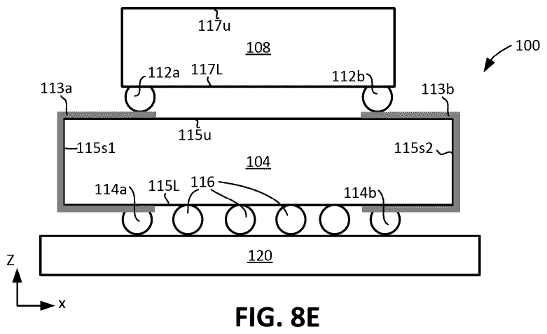

FIG. 7 illustrate a flowchart depicting a method 700 for forming a conductive line 113a of the integrated circuit structure 100 of FIGS. 1-5, in accordance with an embodiment of the present disclosure. FIGS. 8A1, 8A2, 8B1, 8B2, 8C1, 8C2, 8D1, 8D2, and 8E collectively illustrate an example integrated circuit structure 100 in various stages of processing in accordance with the methodology 700 of FIG. 7, in accordance with an embodiment of the present disclosure. FIGS. 7 and 8A1-8E will be discussed in unison.

FIGS. 8A1, 8B1, 8C1, and 8D1 illustrate cross-sectional views of the device 104, e.g., similar to the cross-sectional view of FIG. 1. FIGS. 8A2 and 8B2 are bottom-up views of the device 104, e.g., when viewed along line A-A′ of FIG. 8A1. Thus, FIGS. 8A2 and 8B2 illustrate the lower surface 115L of the device 104.

FIGS. 8C2 and 8D2 are top-down or plan views of the device 104, e.g., when viewed along line B-B′ of FIG. 8C1. Thus, FIGS. 8C2 and 8D2 illustrate the upper surface 115u of the device 104.

The method 700 describes formation of one conductive line 113a, and the processes of the method 700 may be applied to form the various other conductive lines 113 on the device 104.

Referring to the method 700 of FIG. 7, processes 704 and 708 may be performed, or alternatively process 712 may be performed, e.g., depending on techniques used to form the conductive lines 113.

In processes 704 and 708, the deposition/patterning of conductive material on various surfaces of the device 104 are performed using different processes. For example, referring to process 704, first conductive material is deposited on a first surface of device 104; and the first conductive material on the first surface is patterned, to form a first section of the conductive line 113a. Subsequently, at 708, second conductive material is deposited on second and third surfaces of device 104; and the second conductive material on the second and third surfaces is patterned, to form a second section and a third section, respectively, of the conductive line 113a.

The first surface of process 704 can be any one surface of the device 104, and the second and third surfaces of process 708 can be any two remaining surfaces of the device 104. As an example, the first surface of process 704 may be the lower surface 115L of the device 104; and the second and third surfaces of process 708 may be the side surface 115s1 and the upper surface 115u of the device 104. In another example, the first surface of process 704 may be the upper surface 115u of the device 104; and the second and third surfaces of process 708 may be the side surface 115s1 and the lower surface 115L of the device 104.

In one embodiment, the deposition of the first and second conductive materials during processes 704 and 708 may be performed using any appropriate deposition techniques (e.g., conformal deposition techniques), such as sputtering, chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example.

In one embodiment, the patterning of processes 704 and 708 may be performed using laser beams. For example, laser ablation or spallation may be used to pattern the conductive material, and form the conductive lines. For example, the laser beam is moved over the corresponding surfaces using an appropriate technique, e.g., by using a galvo or otherwise steered laser beam, where a galvanometer (which is an electromechanical instrument) is used to deflect the laser beam by using a mirror, such that the laser projection is moved in specific pre-configured pattern on the conductive materials on the corresponding surfaces of the device 104, to selectively remove the first and second conductive materials. Portions of the conductive material not removed by the laser beam remain on the surfaces of the device 104, to form the conductive lines 113.

In an example, the layer 224 of dielectric material (see FIG. 2) may act as a laser-stop layer, e.g., to prevent or at least reduce chances of the laser beam etching, removing, or otherwise adversely affecting or harming a body of the device 104 that is below the layer 224.

In an example, because the second conductive material is deposited on the second and third surfaces using the same deposition process, there may not be a seam or interface between the second and third sections of the conductive line 113a, and the second and third sections of the conductive line 113a may be a monolithic conductive structure.

FIGS. 8A1-8D2 illustrate the device 104 during the processes 704 and 708. In the example of FIGS. 8A1-8D2, the first surface of process 704 is assumed to be the lower surface 115L of the device 104; and the second and third surfaces of process 708 is assumed to be the side surface 115s1 and the upper surface 115u of the device 104.

For example, FIGS. 8A1 and 8A2 illustrate conformal and blanket deposition of the first conductive material 713 on the lower surface 115L of the device 104. FIGS. 8B1 and 8B2 illustrate patterning of the first conductive material 713 on the lower surface 115L of the device 104, e.g., to form the corresponding sections of the conductive lines 113 on the lower surface 115L of the device 104.

FIGS. 8C1 and 8C2 illustrate conformal and blanket deposition of the second conductive material 723 on the upper surface 115u and the side surfaces 115s1 and 115s2 of the device 104. FIGS. 8D1 and 8D2 illustrate patterning of the second conductive material 723 on the upper surface 115u and the side surfaces 115s1 and 115s2 of the device 104, e.g., to form the corresponding sections of the conductive lines 113 on the upper surface 115u and the side surfaces 115s1 and 115s2 of the device 104.

As illustrated in FIG. 7, instead of processes 704 and 708, the process 712 may also be performed. At process 712, conductive material is blanket deposited (e.g., deposited using a same deposition process) on the first, second, and third surfaces of device 104; and the deposited conductive material on the first, second, and third surfaces are patterned (e.g., using a same pattering process), to respectively form the first, second, and third sections of the conductive line 113a. Thus, process 712 combines the processes 704 and 708.

In an example, because the conductive material is deposited on the first, second, and third surfaces using the same deposition process, there may not be a seam or interface between the first, second, and third sections of the conductive line 113a. Thus, the first, second, and third sections of the conductive line 113a (e.g., an entirety of the conductive line 113a) may be a monolithic conductive structure.

The deposition of process 712 may be performed using any appropriate deposition technique (e.g., a conformal deposition technique), such as sputtering, CVD, PVD, ALD, VPE, MBE, or LPE, for example. In one embodiment, the patterning of the process 712 may be performed using a laser beam, e.g., using laser ablation or spallation, as described above.

The method 700 then proceeds from 708 or 712 to 716, where a first interconnect component 112a is coupled to a section of the conductive line 113a that is on the upper surface 115u of the device 104, and a second interconnect component 114a is coupled on another section of the conductive line 113a that is on the lower surface 115L of the device 104, as illustrated in FIG. 8E. In an example, other interconnect components 116 may already be present on the lower surface 115L of the device 104, and/or may be coupled at process 716, as illustrated in FIG. 8E. Although not illustrated in FIG. 7, the devices 108 and 120 may subsequently be coupled to the device 104, e.g., through the interconnect components 112, 114, and 116, e.g., as illustrated in FIG. 8E.

Note that the processes in method 700 are shown in a particular order for ease of description. However, one or more of the processes may be performed in a different order or may not be performed at all (and thus be optional), in accordance with some embodiments. Numerous variations on method 700 and the techniques described herein will be apparent in light of this disclosure.

### Further Example Embodiments

The following examples pertain to further embodiments, from which numerous permutations and configurations will be apparent.

Example 1. A microelectronic device structure comprising: a device having (i) a lower surface, (ii) an upper surface opposite the lower surface, and (iii) a side surface extending between the lower surface and the upper surface; and a conductive line having (i) a first section on the upper surface, (ii) a second section on the side surface, and (iii) a third section on the lower surface; wherein the first section and the second section of the conductive line is a monolithic conductive structure, with no seam or interface between the first section and the second section, and/or the second section and the third section of the conductive line is a monolithic conductive structure, with no seam or interface between the second section and the third section.

Example 2. The microelectronic device structure of example 1, further comprising: a first contact pad on the first section of the conductive line, the first contact pad configured to receive a first interconnect component; and a second contact pad on the third section of the conductive line, the second contact pad configured to receive a second interconnect component.

Example 3. The microelectronic device structure of example 2, further comprising the first interconnect component and the second interconnect component, wherein the first interconnect component is a solder ball or a solder bump, and the second interconnect component is a solder ball or a solder bump.

Example 4. The microelectronic device structure of any one of examples 1-3, wherein the device is a first device, and wherein the integrated circuit structure further comprises: a second device above the first device; and an interconnect component configured to couple the second device to the first section of the conductive line.

Example 5. The microelectronic device structure of example 4, wherein the interconnect component is a first interconnect component, and wherein the integrated circuit structure further comprises: a third device below the first device; and a second interconnect component configured to couple the third section of the conductive line to the third device.

Example 6. The microelectronic device structure of any one of examples 1-5, wherein the first, second, and third sections of the conductive line are part of a monolithic conductive structure, with no seam or interface between the first, second and third sections.

Example 7. The microelectronic device structure of any one of examples 1-6, wherein at least one of the first, second, or third sections of the conductive line comprises: a first segment and a second segment, such that the first segment and the second segment intersect at an intersection point at angle different from 180 degrees.

Example 8. The microelectronic device structure of example 7, wherein a first thickness of the conductive line at the intersection point and a second thickness of the conductive line at a non-intersection point of the first section are within 5% of each other.

Example 9. A system comprising: a first device having (i) a lower surface, (ii) an upper surface opposite the lower surface, and (iii) a side surface extending between the lower surface and the upper surface; a second device above the first device; a third device below the first device; a continuous conductive line extending on the upper surface, the side surface, and the lower surface of the first device, wherein a portion of the conductive line extending on at least two adjacent surfaces of the first die is monolithic, without any seam or interface therewithin; a first interconnect component coupled between (i) the second device, and (ii) a section of the conductive line that on the upper surface of the first device; and a second interconnect component coupled between (i) the third device, and (ii) a section of the conductive line that on the lower surface of the first device.

Example 10. The system of example 9, wherein: the first device is first integrated circuit die or a first integrated circuit package; the second device is a second integrated circuit die or a second integrated circuit package; and the third device is a third integrated circuit die, a third integrated circuit package, or a circuit board.

Example 11. The system of any one of examples 9-10, wherein the first interconnect component is a solder ball or a solder bump, and the second interconnect component is a solder ball or a solder bump.

Example 12. The system of any one of examples 9-11, wherein: a section of the conductive line, which extends on one of the lower, side, or upper surfaces of the first die, comprises a first segment and a second segment, such that the first segment and the second segment intersect at an intersection point at angle different from 180 degrees; and a first thickness of the conductive line at the intersection point and a second thickness of the conductive line at a non-intersection point of the section is within 5% of each other.

Example 13. A method comprising: depositing first conductive material on a first surface of an integrated circuit device; patterning the first conductive material on the first surface, to form a first section of a conductive line; depositing second conductive material on a second surface and a third surface of the integrated circuit device, one of the second or third surfaces is substantially perpendicular to the first surface; and patterning the second conductive material on the second and third surfaces, to form a second section and a third section of the conductive line on the second surface and the third surface, respectively, of the integrated circuit device, such that the conductive line is a continuous structure that extends on the first surface, the second surface, and the third surface of the integrated circuit device.

Example 14. The method of example 13, further comprising: coupling a first interconnect component on the first section of the conductive line that is on the first surface; and coupling a second interconnect component on the third section of the conductive line that is on the third surface that is opposite to the first surface.

Example 15. The method of example 14, wherein the integrated circuit device is a first integrated circuit device, and wherein the method further comprises: coupling a second integrated circuit device to the first interconnect component, and coupling a third integrated circuit device to the second interconnect component.

Example 16. The method of any one of examples 14-15, wherein the first interconnect component is a solder ball or a solder bump, and the second interconnect component is a solder ball or a solder bump.

Example 17. The method of any one of examples 13-16, wherein the first conductive material and the second conductive material are deposited using a same deposition process.

Example 18. The method of any one of examples 13-17, wherein the first conductive material and the second conductive material are patterned using a same patterning process.

Example 19. The method of any one of examples 13-18, wherein the second conductive material is deposited subsequent to patterning the first conductive material.

Example 20. The method of any one of examples 13-19, wherein patterning the first conductive material and the second conductive material comprises: patterning the first conductive material and the second conductive material using corresponding laser beams.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future-filed applications claiming priority to this application may claim the disclosed subject matter in a different manner and generally may include any set of one or more limitations as variously disclosed or otherwise demonstrated herein.

What is claimed is:

1. A microelectronic device structure comprising:
a device having (i) a lower surface, (ii) an upper surface opposite the lower surface, and (iii) a side surface extending between the lower surface and the upper surface; and
a conductive line having (i) a first section on the upper surface, (ii) a second section on the side surface, and (iii) a third section on the lower surface;
wherein
the first section and the second section of the conductive line is a monolithic conductive structure, and/or
the second section and the third section of the conductive line is a monolithic conductive structure.

2. The microelectronic device structure of claim 1, further comprising:
a first contact pad on the first section of the conductive line, the first contact pad configured to receive a first interconnect component; and
a second contact pad on the third section of the conductive line, the second contact pad configured to receive a second interconnect component.

3. The microelectronic device structure of claim 2, further comprising the first interconnect component and the second interconnect component, wherein the first interconnect component is a solder ball or a solder bump, and the second interconnect component is a solder ball or a solder bump.

4. The microelectronic device structure of claim 1, wherein the device is a first device, and wherein the integrated circuit structure further comprises:
a second device above the first device; and
an interconnect component configured to couple the second device to the first section of the conductive line.

5. The microelectronic device structure of claim 4, wherein the interconnect component is a first interconnect component, and wherein the integrated circuit structure further comprises:
a third device below the first device; and
a second interconnect component configured to couple the third section of the conductive line to the third device.

6. The microelectronic device structure of claim 1, wherein the first, second, and third sections of the conductive line are part of a monolithic conductive structure, with no seam or interface between the first, second and third sections.

7. The microelectronic device structure of claim 1, wherein at least one of the first, second, or third sections of the conductive line comprises:
a first segment and a second segment, such that the first segment and the second segment intersect at an intersection point at angle different from 180 degrees.

8. The microelectronic device structure of claim 7, wherein a first thickness of the conductive line at the intersection point and a second thickness of the conductive line at a non-intersection point of the first section are within 5% of each other.

9. A system comprising:
a first device having (i) a lower surface, (ii) an upper surface opposite the lower surface, and (iii) a side surface extending between the lower surface and the upper surface;
a second device above the first device;
a third device below the first device;
a continuous conductive line extending on the upper surface, the side surface, and the lower surface of the first device, wherein a portion of the conductive line extending on at least two adjacent surfaces of the first die is monolithic;
a first interconnect component coupled between (i) the second device, and (ii) a section of the conductive line that on the upper surface of the first device; and
a second interconnect component coupled between (i) the third device, and (ii) a section of the conductive line that on the lower surface of the first device.

10. The system of claim 9, wherein:
the first device is first integrated circuit die or a first integrated circuit package;
the second device is a second integrated circuit die or a second integrated circuit package; and
the third device is a third integrated circuit die, a third integrated circuit package, or a circuit board.

11. The system of claim 9, wherein the first interconnect component is a solder ball or a solder bump, and the second interconnect component is a solder ball or a solder bump.

12. The system of claim 9, wherein:
a section of the conductive line, which extends on one of the lower, side, or upper surfaces of the first die, comprises a first segment and a second segment, such that the first segment and the second segment intersect at an intersection point at angle different from 180 degrees; and
a first thickness of the conductive line at the intersection point and a second thickness of the conductive line at a non-intersection point of the section is within 5% of each other.

13. A method comprising:
depositing first conductive material on a first surface of an integrated circuit device;
patterning the first conductive material on the first surface, to form a first section of a conductive line;
depositing second conductive material on a second surface and a third surface of the integrated circuit device, one of the second or third surfaces is substantially perpendicular to the first surface; and
patterning the second conductive material on the second and third surfaces, to form a second section and a third section of the conductive line on the second surface and the third surface, respectively, of the integrated circuit device, such that the conductive line is a continuous structure that extends on the first surface, the second surface, and the third surface of the integrated circuit device.

14. The method of claim 13, further comprising:
coupling a first interconnect component on the first section of the conductive line that is on the first surface; and
coupling a second interconnect component on the third section of the conductive line that is on the third surface that is opposite to the first surface.

15. The method of claim 14, wherein the integrated circuit device is a first integrated circuit device, and wherein the method further comprises:
coupling a second integrated circuit device to the first interconnect component, and coupling a third integrated circuit device to the second interconnect component.

16. The method of claim 14, wherein the first interconnect component is a solder ball or a solder bump, and the second interconnect component is a solder ball or a solder bump.

17. The method of claim 13, wherein the first conductive material and the second conductive material are deposited using a same deposition process.

18. The method of claim 13, wherein the first conductive material and the second conductive material are patterned using a same patterning process.

19. The method of claim 13, wherein the second conductive material is deposited subsequent to patterning the first conductive material.

20. The method of claim 13, wherein patterning the first conductive material and the second conductive material comprises:
patterning the first conductive material and the second conductive material using corresponding laser beams.
